(19) United States
(12) Patent Application Publication
(10) Pub. No.: US 2011/0233723 A1
(43) Pub. Date: Sep. 29, 2011

(54) DIELECTRIC FILM AND SEMICONDUCTOR DEVICE

(75) Inventor: Masami TANIOKU, Tokyo (JP)

(73) Assignee: ELPIDA MEMORY, INC., Tokyo (JP)

(21) Appl. No.: 13/069,968

(22) Filed: Mar. 23, 2011

(30) Foreign Application Priority Data
Mar. 25, 2010 (JP) 2010-069975

(51) Int. Cl. H01L 29/40; C04B 35/46

(52) U.S. Cl. 257/532; 501/134; 257/E29.111

(57) ABSTRACT

Disclosed is a dielectric film having a high dielectric constant and an excellent leakage breakdown. The dielectric film includes a TiO₂ film containing Zr or Al in a concentration of less than 40% by a ratio of the number of atoms represented by (Zr or Al)/((Zr or Al)+Ti) with an approximately constant concentration profile in the direction of the film thickness. The dielectric film is suitable for a dielectric film of a semiconductor device, particularly a capacitor dielectric film.

### BACKGROUND OF THE INVENTION

1. Field of the Invention

The present invention relates to a dielectric film and a semiconductor device such as DRAM (Dynamic Random Access Memory) having a capacitor, and more particularly, to a capacitor dielectric film used in a capacitor of DRAM and the like and a method of fabricating the same.

2. Description of the Related Art

As semiconductor devices such as a DRAM and the like become miniaturized, the application of TiO₂ to a high dielectric film is considered to form a capacitor having a high capacitance. In addition to the magnitude of capacitance, a capacitor used in a memory cell of DRAM is also required to have low leakage current. TiO₂ film is an insulating film having a high dielectric constant of about 80, but the TiO₂ may have a problem that the leakage current thereof is large because a band gap width thereof is narrow. For that reason, a capacitor in which pure TiO₂ film is directly used as a capacitor dielectric film cannot be applied to a memory cell of DRAM.

To solve the problem, conventional techniques disclose combining of TiO₂ film with other material having a wide band gap width (see Japanese Patent Application Publication Nos. 2007-013086 and 2009-027017).

Japanese Patent Application Publication Nos. 2007-013086 discloses a method of depositing TiO₂ and ZrO₂ alternately. In the method, however, there is a problem in that the effect of reducing the leakage current is not enough (details will be reviewed in the description of exemplary embodiment 3).

### SUMMARY OF THE INVENTION

The present inventor has been proposed a method for reducing a leakage current by adding another element, particularly, an element of lanthanoids into the TiO₂ film (see Japanese Patent Application Publication No. 2009-027017). The present inventor has further investigated other additive elements not disclosed in Japanese Patent Application Publication No. 2009-027017 and achieved to the following inventions.

That is, in one aspect, the present invention provides a dielectric film comprising a TiO₂ film containing Zr or Al in a concentration of less than 40% by a ratio of the number of atoms represented by (Zr or Al)/((Zr or Al)+Ti) with an approximately constant concentration profile in the direction of the film thickness.

In another aspect, the present invention provides a semiconductor device comprising a capacitor, the capacitor a lower electrode, a capacitor dielectric film on the lower electrode and an upper electrode on the capacitor dielectric film, wherein the capacitor dielectric film includes a TiO₂ film containing Zr or Al in a concentration of less than 40% by a ratio of the number of atoms represented by (Zr or Al)/((Zr or Al)+Ti) with an approximately constant concentration profile in the direction of the film thickness.

In still another aspect, the present invention provides a semiconductor device including at least one dielectric film, wherein the dielectric film comprises a TiO₂ film containing Zr or Al in a concentration of less than 40% by a ratio of the number of atoms represented by (Zr or Al)/((Zr or Al)+Ti) with an approximately constant concentration profile in the direction of the film thickness.

According to an exemplary embodiment of the present invention, a capacitor in which a leakage current is small and a capacitance is large can be easily formed. Even in a case where a memory cell is miniaturized in its size, a DRAM device having an excellent refresh characteristic (data maintaining characteristic) can easily be formed by applying a capacitor of the present invention to a memory cell of a DRAM device.

### BRIEF DESCRIPTION OF THE DRAWINGS

The above features and advantages of the present invention will be more apparent from the following description of certain preferred embodiments taken in conjunction with the accompanying drawings, in which

FIG. 1 is a sectional view showing the stack structure of a capacitor;

FIG. 2 is a sectional view showing the stack structure of a specimen;

FIG. 3 is a graph showing the relationship between a leakage breakdown or dielectric constant of TiO₂ film and an added amount of Zr;

FIG. 4 is a graph showing the relationship between a leakage breakdown or dielectric constant of TiO₂ film and an added amount of Al;

FIG. 5 is a schematic view showing a film deposition apparatus used in an ALD method according to an exemplary embodiment of the present invention;

FIG. 6 is a flow chart illustrating fabrication processes using the apparatus shown in FIG. 5 according to an exemplary embodiment of the present invention;

FIG. 7 is a flow chart illustrating fabrication processes in the ALD method according to a conventional example;

FIG. 8 is a conceptual view showing a plan layout of a memory cell part in a DRAM device as a semiconductor device according to an exemplary embodiment of the present invention;

FIG. 9 is a sectional view showing a section structure of a semiconductor device taken along a parallel direction to a bit wiring layer according to an exemplary embodiment of the present invention;

FIG. 10 is a sectional view illustrating a process of fabricating a capacitor according to an exemplary embodiment of the present invention;

FIG. 11 is a sectional view illustrating a process of fabricating a capacitor according to an exemplary embodiment of the present invention; and

FIG. 12 is a sectional view illustrating a process of fabricating a capacitor according to an exemplary embodiment of the present invention.

### DETAILED DESCRIPTION OF THE PREFERRED EMBODIMENTS

The invention will be now described herein with reference to exemplary embodiments. Those skilled in the art will recognize that many alternative embodiments can be accomplished using the teachings of the present invention and that the invention is not limited to the embodiments illustrated for explanatory purpose.

FIG. 1 schematically shows a vertical section of a capacitor formed according to the present invention. The capacitor includes capacitor dielectric film 2 sandwiched between lower electrode 1 and upper electrode 3. Lower electrode 1 and upper electrode 3 are formed of a metal film. The metal film comprises a metal material such as Ru, Pt, Ir, W and Ta, or a nitride material such as TiN, WN and TaN. The electrode can be formed of a film containing a plurality of materials or a film of stacked structure of a plurality of materials.

Capacitor dielectric film 2 is an insulating film of TiO₂ film containing Zr or Al in a concentration of less than 40% by a ratio of the number of atoms represented by (Zr or Al)/((Zr or Al)+Ti) with an approximately constant concentration profile in the direction of the film thickness.

### Exemplary Embodiment 1

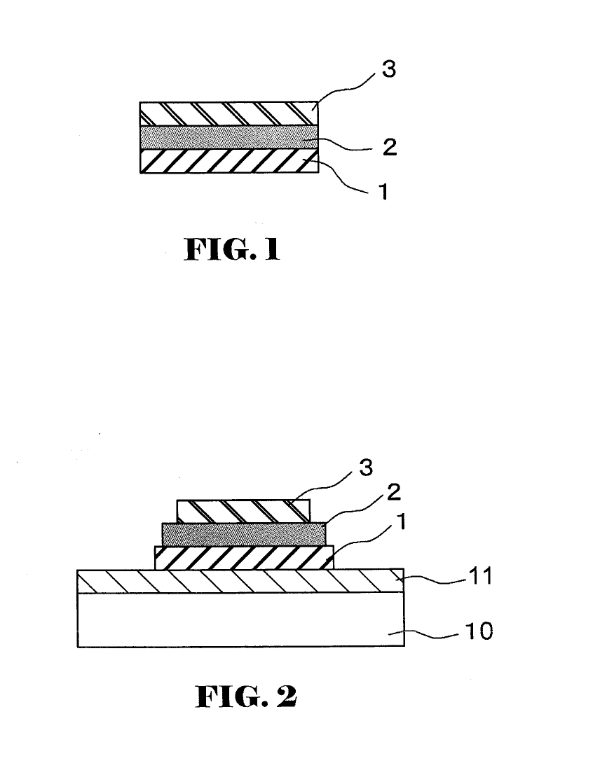

FIG. 2 is a sectional view showing a stack structure of a specimen according to an exemplary embodiment of the present invention.

In FIG. 2, reference number “10” denotes a semiconductor substrate formed of Si, “11” denotes an insulating film formed of SiO₂, and “1”, “2” and “3” denote a lower electrode, a capacitor dielectric film and an upper electrode, respectively.

To obtain the stack structure shown in FIG. 2, first, semiconductor substrate 10 is prepared, which is formed thereon with insulating film 11 for preventing diffusion from each other. Next, lower electrode 1 is formed by forming a Pt film of 100 nm thickness on insulating film 11 by means of a sputtering method.

Next, to compare experimental results, the capacitor dielectric film formed of only TiO₂ film will be formed without additives of Zr and Al as follows.

Capacitor dielectric film 2 is formed of only TiO₂ on lower electrode 1 by means of a sputtering method. First, TiO₂ target is set in a chamber of a sputtering apparatus, semiconductor substrate 10 formed thereon with even lower electrode 1 is heated to a temperature of 300° C., and Ar and O₂ gases are simultaneously supplied into the chamber so that the pressure of 0.5 Pa is maintained therein. RF power (high frequency) of 150 W is supplied to a TiO₂ target and discharged while semiconductor substrate 10 revolves at a position opposite the target revolves thereby a TiO₂ film is deposited on lower electrode 1, so that capacitor dielectric film 2 is obtained.

Next, upper electrode 3 is formed with a Pt film of 30 nm on semiconductor substrate 10 on which capacitor dielectric film 2 has been formed, by means of a sputtering method.

In succession, heat treatment as a post annealing is performed at O₂ atmosphere of 600° C. during 3 minutes. In this manner, a stack structure having capacitor dielectric film 2 formed of TiO₂ having no additive Zr can be obtained.

Next, as will be described below, it is formed a stack structure having capacitor dielectric film 2 formed of TiO₂ film in which additive Zr is added within a range of 100% by a ratio of Zr/(Zr+Ti).

First, Si substrate 10, on which even lower electrode 1 has been formed, is prepared in the same structure as a stack structure having capacitor dielectric film 2 formed of TiO₂ film having additive Zr of 0%.

Capacitor dielectric film 2 is formed as follows. First, TiO₂ target and ZrO₂ target are set in a chamber of a sputtering apparatus, semiconductor substrate 10 on which even lower electrode 1 is formed is heated to a temperature of 300° C., Ar and O₂ gases are simultaneously supplied into a chamber of a sputtering apparatus thereby the chamber is maintained at a pressure of 0.5 Pa. Under this state, RF (high frequency) power is supplied to a TiO₂ target and ZrO₂ target and discharged while semiconductor substrate 10 revolves thereby TiO₂ film containing Zr is deposited on lower electrode 1. The concentration of Zr element contained in TiO₂ film can be controlled by controlling independently an intensity of RF power supplied to each of the targets. Also, Zr is nearly uniformly distributed in the TiO₂ film formed in such a manner.

Next, upper electrode 3 is formed on semiconductor substrate 10 having been formed thereon with capacitor dielectric film 2, and post annealing is performed in the same manner as the previous post annealing.

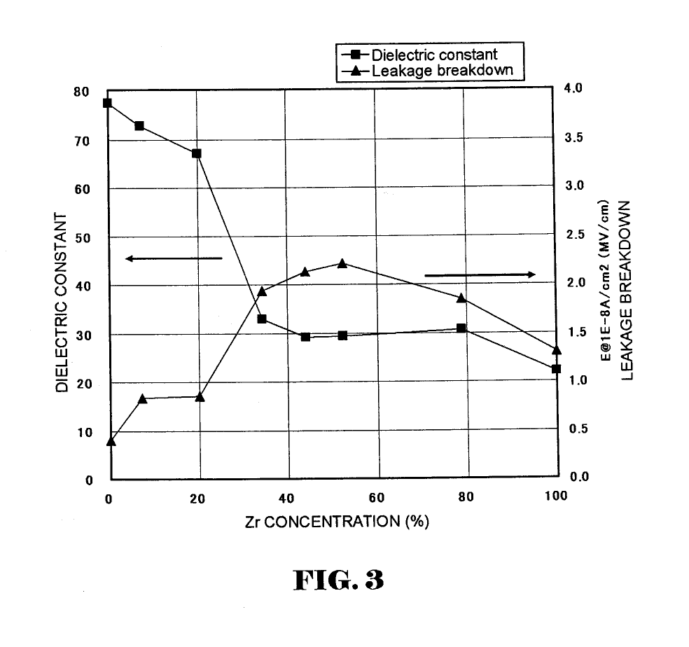

Regarding a plurality of capacitors prepared by forming capacitor dielectric film 2 as a specimen in a film thickness of 40 nm and changing a concentration of Zr contained in the capacitor dielectric film 2, electrical characteristics thereof are measured and shown in FIG. 3. A horizontal axis represents a concentration of Zr contained in the TiO₂ film, a left vertical axis represents dielectric constant, and a right vertical axis represents the result of measured leakage breakdown.

The concentration of Zr corresponds to a value represented by a ratio of Zr/(Zr+Ti), and can be measured using the Rutherford backscattering spectrometry (RBS). A dielectric film a concentration of Zr is 100% corresponds to pure ZrO2 and a dielectric film a concentration of Zr is 0% corresponds to pure TiO₂.

Leakage breakdown is defined by a value of electric field applied between electrodes when a leakage current density flowing between electrodes becomes 1×10⁻⁸ A/cm².

From FIG. 3, it is found that the leakage breakdown is minimized when an amount of added Zr is 0% and maximized when an amount of added Zr is in a concentration range of about 40 to 60%.

Also, it is found that the dielectric constant is maximized when an added amount of Zr is 0% and becomes lowered as Zr is added thereto. The dielectric constant becomes about 45 when a concentration of Zr is 30%. This is a sufficiently large value compared with the dielectric constant of ZrO₂ (about 25) that is widely used as a capacitor dielectric film.

A capacitor mounted on a memory cell of a DRAM after the 40 nm design rule generation requires a dielectric constant larger than that of a currently used ZrO₂. In more detail, it requires a dielectric constant of more than 30. As a necessary condition for satisfying a condition of dielectric constant and enhancing a leakage breakdown relating to a TiO₂ film having no additives, a concentration of Zr contained in a TiO₂ film can be set as 10 to 40%, preferably 20 to 30%.

Also, although the annealing temperature is not limited to 600° C., it is preferable that the annealing is performed in an oxygen atmosphere in a temperature range of 400 to 700° C.

### Exemplary Embodiment 2

Instead of adding Zr, Al is added to TiO₂ film to thereby form a capacitor dielectric film, and then an evaluation of the resultant capacitor dielectric film is performed.

In a similar manner to Exemplary Embodiment 1, a plurality of capacitors is prepared by changing a concentration of Al contained in a TiO₂ film.

To add Al to the TiO₂ film, an Al₂O₃ target and a TiO₂ target are set in a chamber to use a sputtering method, and RF power applied is independently controlled.

As shown in FIG. 2, the stack structure including capacitor dielectric film 2 formed of a TiO₂ film is formed. The amount of additive Al contained in the TiO₂ film can be changed within 70% by a ratio of Al/(Al+Ti). At this time, a post annealing is performed in an oxygen atmosphere set at a temperature of 500° C.

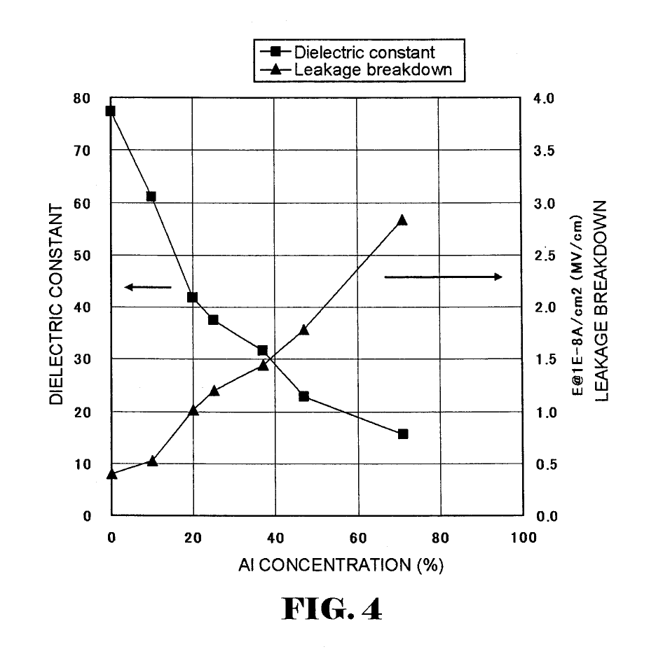

In the same manner as Exemplary Embodiment 1, the dielectric constant and leakage breakdown of the capacitor are measured and the results are shown in FIG. 4. A horizontal axis denotes a concentration of Al which corresponds to Al/(Al+Ti).

From FIG. 4, it is found that the leakage breakdown is minimized when an amount of additive Al is 0% and the leakage breakdown increases as an amount of additive Al increases.

Incidentally, it is found that the dielectric constant is maximized when an added amount of Al is 0% and becomes lowered as Al is added thereto. The dielectric constant becomes about 30 when a concentration of Al is 40%. This is a sufficiently large value compared with the dielectric constant of Al₂O₃ (about 9) and is also a large value even compared with the dielectric constant (about 25) of ZrO₂.

A capacitor mounted on a memory cell of a DRAM after the 40 nm design rule generation requires a dielectric constant larger than that of a currently used ZrO₂. As a necessary condition for making the dielectric constant more than 30 and enhancing a leakage breakdown to more than that of the TiO₂ film having no additive, a concentration of Al contained in a TiO₂ film can be set as 10 to 40%, preferably 20 to 30%.

### Exemplary Embodiment 3

A method of forming a capacitor dielectric film, which is applied to a capacitor according to the present invention, using an ALD (Atomic Layer Deposition) method, will now be described.

As a detailed example, a method of forming a TiO₂ film containing Zr will be described.

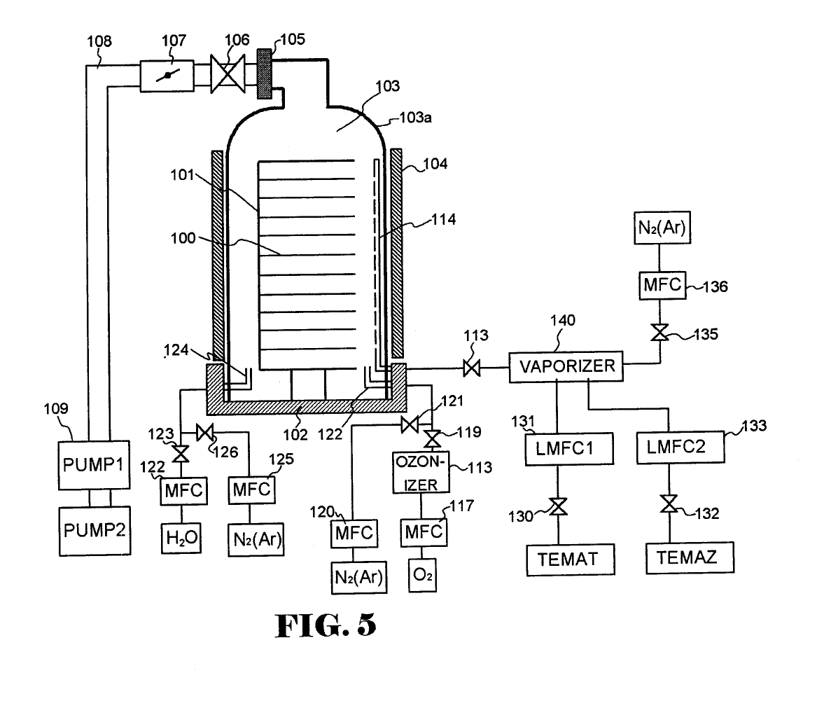

FIG. 5 is a schematic view showing a vertical batch processing type of an ALD apparatus employing a furnace.

The vertical batch processing type of ALD apparatus is capable of forming capacitor dielectric films simultaneously on a plurality of semiconductor substrates.

In the ALD apparatus shown in FIG. 5, a vacuum discharge vent is installed at the top of reaction tube 103a forming reaction chamber 103 and connected to vacuum valve 106 through connection member 105. The vacuum discharge vent is connected to vacuum pump 109 through pressure control valve 107 and vacuum discharge pipe 108. Reaction chamber 103 is installed therein with boat 101 which is supported by boat loader 102 and enables mounting of a plurality of semiconductor substrates 100 therein. Also, heater 104 is in contact with the outside of reaction tube 103a.

As raw materials forming films, a TEMAT (tetra ethyl methyl amino titanium: Ti[N(CH₃)(C₂H₅)]₄) source of supply and a TEMAZ (tetra ethyl methyl amino zirconium: Zr[N(CH₃)(C₂H₅)]₄) source of supply are provided. The TEMAT source of supply is connected to vaporizer 140 through TEMAT inlet valve 130 and liquid mass flow controller (LMFC1) 131. The TEMAZ source of supply is connected to vaporizer 140 through TEMAZ inlet valve 132 and liquid flow rate controller (LMFC2) 133. In the vaporizer 140, the TEMAT (Ti source) and TEMAZ (Zr source) are supplied in a predetermined flow rate by liquid mass flow controllers 131 and 132, sprayed through spray nozzles thereby being mixed with each other, and vaporized in a vaporization chamber, thereby source gases containing Ti and Zr in a predetermined ratio are generated.

The source gases mixed and vaporized through vaporizer 140 are supplied from gas injector 114 having a plurality of small holes to reaction chamber 103 through valve 113. The plurality of small holes of gas injector 114 is formed so as to respond to each substrate installing place of a plurality of semiconductor substrates 100. Vaporizer 140 is connected to N₂ or Ar source of supply through valve 135 for introducing carrier gases and mass flow controller (MFC) 136. Source gasses may be supplied in a state diluted with carrier gases.

Incidentally, Ti source and Zr source can be mixed after having become a gas state. That is, Ti source gas (first source gas) is created with only TEMAT (Ti source) through the vaporizer and Zr source gas (second source gas) is created with only TEMAZ (Zr source) through other vaporizer, and thereafter the first and second source gases are mixed in a predetermined ratio to be supplied to reaction chamber 103.

O₃ gas as a reaction gas (oxidation gas) is supplied from O₂ source of supply to a reaction chamber through mass flow controller (MFC) 117, O₃ generator (ozone generator) 113 and O₃ inlet valve 119. To purge an O₃ supply pipe, N₂ or Ar is supplied from N₂ or Ar source of supply through mass flow controller (MFC) 120 and valve 121.

Water vapor (H₂O) as other reaction gas is connected from H₂O source of supply to gas injector 124 through mass flow controller (MFC) 122 and valve 123. To purge a H₂O supply pipe, N₂ or Ar gas is supplied from a N₂ or Ar source of supply through mass flow controller (MFC) 125 and valve 126.

As oxidation gas, ozone and water vapor all may be used. Also, an oxygen gas supplying system is provided thereby oxidation can be performed using a mixed gas of oxygen and ozone or a mixed gas of nitrogen and oxygen.

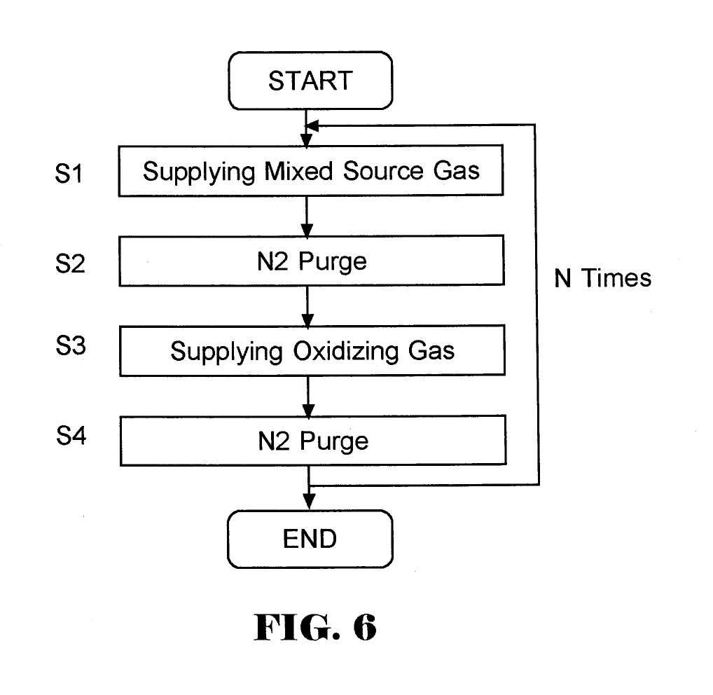

FIG. 6 is a flow chart showing processes for forming capacitor dielectric film containing Zr according to the present invention.

As a detailed example, a case where N₂ as a purge gas is used and O₃ as an oxidation gas is used will now be described.

Semiconductor substrate having been formed thereon with a lower electrode is loaded on boat 101 of the ALD apparatus, and thereafter the boat is installed in reaction chamber 103.

The reaction chamber is maintained at a predetermined pressure and in a temperature range of about 200 to 250° C.

A mixing ratio of sources introduced into vaporizer 140 is controlled by liquid mass flow controllers 131 and 132 controlling separately the flow rate of TEMAT and TEMAZ.

The mixed source gas of Ti and Zr vaporized by vaporizer 140 is supplied into reaction chamber 103 by valve 113 controlling the gas flow rate. At this time, N₂ or Ar as a carrier gas may be introduced into vaporizer 140 through valve 135, and the mixed gas is thereby diluted to be supplied into a reaction chamber.

In process S1 shown in FIG. 6, the mixed source gas is supplied for a predetermined time thereby Ti and Zr are adhered to the lower electrode.

In succession, in process S2, N₂ gas is supplied into a reaction chamber through valve 126 for a predetermined time thereby purging the chamber. Accordingly, a mixed source gas remaining in the chamber without being adhered to a semiconductor substrate is discharged to the outside through vacuum pump 109.

Next, in process S3, ozone gas is supplied into a reaction chamber through valve 119 for a predetermined time, thereby oxidizing Ti and Zr. Thereby TiO₂ film containing Zr is formed in a thickness of atomic layer level.

In process S4, N₂ gas is supplied into a reaction chamber through valve 126 during a predetermined time thereby purging the chamber. Thereby ozone gas remaining in the reaction chamber is discharged to the outside through vacuum pump 109.

By repeating such a series of processes S1 to S4 N times (N: positive integer), TiO₂ film containing Zr can be formed to a predetermined film thickness.

The semiconductor substrate having been formed thereon with a capacitor dielectric film is taken out of the ALD apparatus, and then is annealed at an oxygen atmosphere. Thereafter, an upper electrode is formed on the capacitor dielectric film thereby a capacitor is completed.

Herein, for comparison, a method of forming capacitor dielectric film by a nano-mixing method, which is disclosed in Japanese Patent Application Publication No. 2009-027017, will be described as a conventional example.

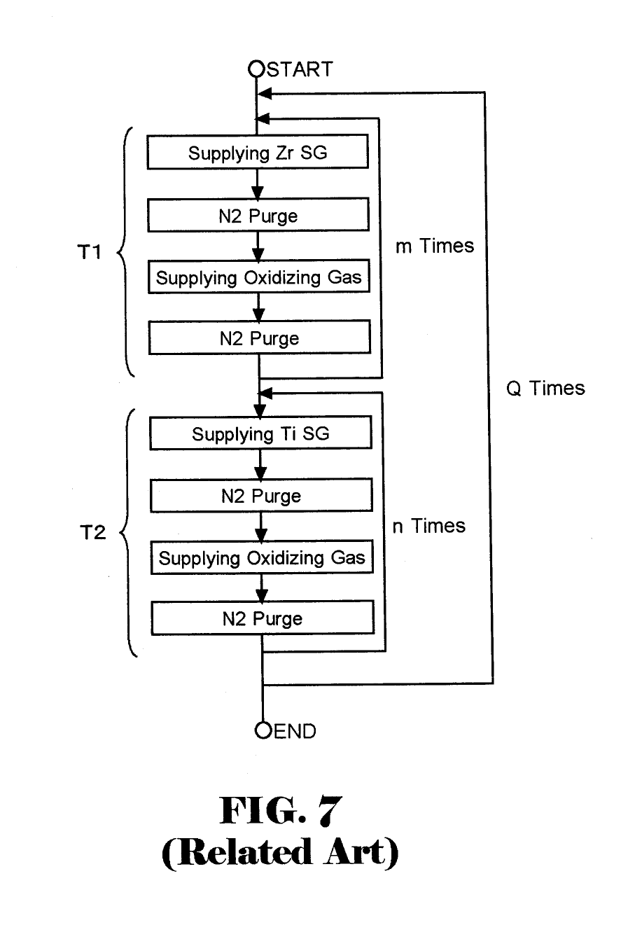

FIG. 7 is a flow chart showing processes for forming a capacitor dielectric film by means of the nano-mixing method using the ALD apparatus.

The nano-mixing method, as described in Japanese Patent Application Publication No. 2009-027017, is a method of depositing alternately a ZrO₂ film and a TiO₂ film to a film thickness of less than 1 nm.

First, in process T1, by repeating m (m: positive integer) times a series of processes including supplying of a Zr source gas (Zr SG), N₂ purge, supplying of an oxidizing gas and N₂ purge, a ZrO₂ film is formed to a predetermined film thickness of less than 1 nm.

Next, in process T2, by repeating n (n: positive integer) times a series of processes including supplying of a Ti source gas (Ti SG), N₂ purge, supplying of an oxidizing gas and N₂ purge, a TiO₂ film is formed to a predetermined film thickness of less than 1 nm.

By repeating Q times (Q: positive integer) a whole cycle including such process T1 and process T2, an insulating film in which ZrO₂ film and TiO₂ film are nano-mixed is formed. This structure is regarded as a stack state of films of less than 1 nm in a microscopic view point.

In this method, the ratio of Zr and Ti contained in an insulating film finally formed may be changed by controlling the values of m and n.

If Zr and Ti are equally contained in the insulating film (a concentration of Zr is 50%), such a method is effective, in contrast, if Zr is contained in a ratio of less than 50%, the thickness of consecutively stacked TiO₂ layers becomes thicker than the thickness of consecutively stacked ZrO₂ layers thereby the insulating film as a whole is not balanced. For this reason, there is a problem that the required electrical characteristics cannot be obtained. This is because the whole thickness of consecutive TiO₂ layers becomes thick thereby the effect of expanding a band gap width cannot be demonstrated sufficiently.

Further, Japanese Patent Application Publication No. 2009-027017 discloses a method of forming a [ZrO₂]ₓ[TiO₂](₁₋ₓ) film of amorphous in which ZrO₂ and TiO₂ is nano-mixed using ZrTi(MMP)₂(OiPr)₅ as a raw material, in a second embodiment. However, such a method, which uses a raw material containing Zr and Ti in a ratio of 1:1 from the beginning, makes it difficult to randomly set a ratio of Zr contained in a film. That is, it is difficult to form a capacitor dielectric film of less than 40% in a ratio of additive Zr, as shown in Exemplary Embodiment 1 of the present invention.

In contrast, the present invention allows forming an insulating film in which Zr and Ti are mixed in an atomic level, not a nano-mixing level, using a Zr containing material and a Ti containing material.

That is, the present invention allows not to form alternately thin films to a film thickness of less than 1 nm but to deposit films in a state that Zr in a predetermined ratio is uniformly contained in a TiO₂ film in an atomic level from the beginning. Accordingly, the concentration profile in the direction of the film thickness is approximately constant.

Thereby, a concentration of Zr in the TiO₂ film can be changed freely. Also, the effect of expanding the band gap width can sufficiently be demonstrated thereby making it possible to easily form a capacitor dielectric film excellent in a leakage breakdown.

A capacitor dielectric film is formed using an ALD method thereby making it possible to form a capacitor dielectric film covering a surface of a lower electrode in a uniform film thickness even in a case where a lower electrode has a 3-dimensional structure.

In this exemplary embodiment, a method of forming a TiO₂ film containing Zr using an ALD apparatus has been described.

In a case where a TiO₂ film containing Al is formed, a vaporized gas as an Al source gas is formed using, for example, TMA (trimethyl-aluminum: Al(CH₃)₃), thereby it is mixed with Ti source gas in a predetermined ratio, and then supplied to the ALD apparatus.

Even in the case of TiO₂ film containing Al, such a film can be formed in the same manner using the ALD apparatus. When applying the film to a semiconductor device, it is preferable that characteristics required in capacitor and mass productivity at a time of manufacture are considered thereby any optimum one is selected among Al and Zr to be added to the TiO₂ film.

### Exemplary Embodiment 4

Next, a case of forming a capacitor included in a memory cell of a DRAM device will now be described as an additional detailed example according to the present invention.

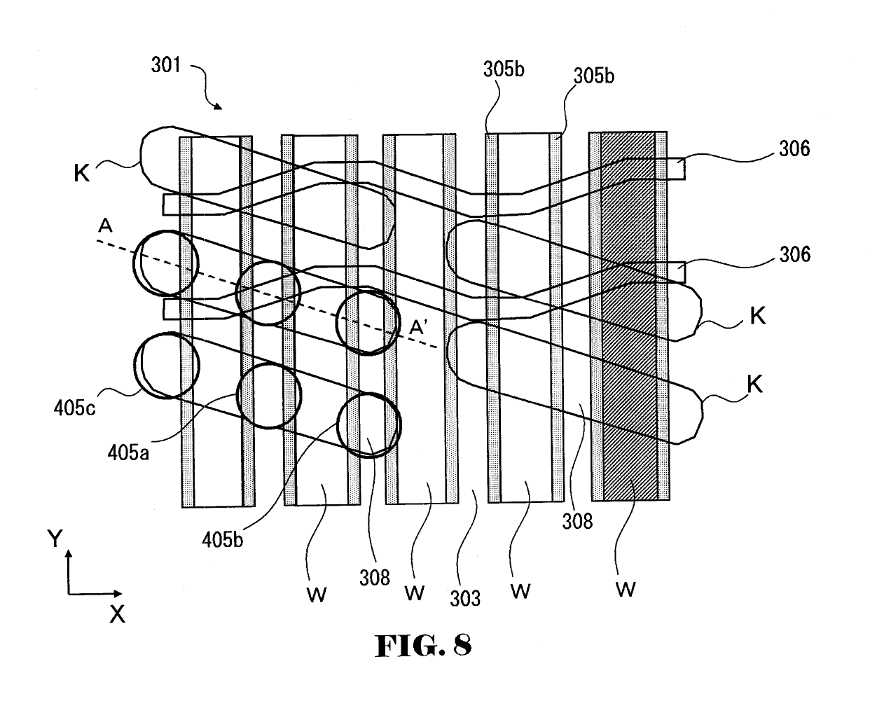

FIG. 8 is a conceptual view showing a plan layout of a memory cell part of a DRAM device as a semiconductor device according to the present invention. FIG. 8 shows at the right a section taken along gate electrode 305 (which will be described later) becoming word line W and side wall 305b.

Also, for simplicity, a capacitor is not shown in FIG. 8, but is shown only in a sectional view.

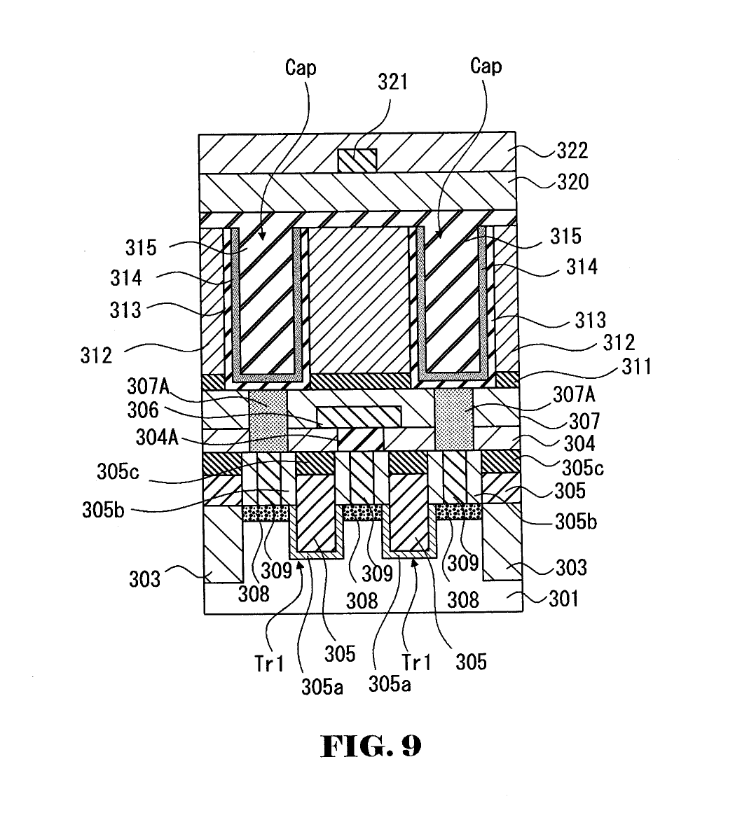

FIG. 9 is a schematic sectional view taken along line A-A′ of a memory cell part shown in FIG. 8. Incidentally, these drawings are for illustrating just the structure of a semiconductor device, but specific dimensions or sizes of each part shown in the drawings may be different from these of practical semiconductor device.

The memory cell part, as shown in FIG. 9, includes switching devices such as MOS transistors Tr1 for a memory cell and capacitors (Cap) connected to MOS transistors Tr1 through a plurality of contact plugs.

In FIG. 8 and FIG. 9, semiconductor substrate 301 is formed of Si containing P type impurities having a predetermined concentration. Semiconductor substrate 301 is formed therein with element isolation regions 303. Element isolation regions 303 are formed at portions other than active regions K by burying insulating films such as SiO₂ in semiconductor substrate 301 by means of STI (shallow trench isolation) method, and serves to insulation-isolate adjacent active regions K. In this exemplary embodiment, the present invention is applied to a cell structure in which 2-bit memory cell is arranged in one active region K.

In the exemplary embodiment of the present invention, a plurality of refectory rectangle shaped active regions K each is arranged at a predetermined interval on the slant like a plan structure shown in FIG. 8, that is, which is arranged according to a layout called 6F2 type memory cell.

Impurity diffusion layers are separately formed on a center portion and both edge portions of each active region K and function as source/drain electrodes of MOS transistors Tr1. Positions of substrate contact portions 405a, 405b, 405c have been determined so that the substrate contact portions can be arranged on the source/drain electrodes (impurity diffusion layers).

Bit line 306 is extended in an angulated shape (bended shape) along a horizontal direction (X direction) shown in FIG. 8, and a plurality of bit lines 306 is arranged at a predetermined interval in a vertical direction (Y direction). Also, a plurality of straight line shaped word lines W is extended and arranged in a vertical direction (Y direction) as shown in FIG. 8. The plurality of word lines W each is arranged at a predetermined interval along a horizontal direction (X axis) as shown in FIG. 8. The word line W is configured to include gate electrodes 305 shown in FIG. 9 at an intersected portion with each active region K. In this embodiment, MOS transistor Tr1 is provided with a recess type of gate electrode.

As shown in a sectional view of FIG. 9, in semiconductor substrate 301, impurity diffusion layers 308 functioning source/drain electrodes are separately formed at active regions K sectioned by element isolation regions 303, and recess type gate electrodes 305 are formed between impurity diffusion layers 308.

Gate electrodes 305 are formed to protrude from an upper portion of semiconductor substrate 301 by a multilayer film formed of polycrystalline silicon film and metal film, the polycrystalline silicon film can be formed by implanting therein impurities such as phosphorus and the like when forming a film by means of a CVD method. A metal film for a gate electrode can be formed of refractory metals such as W or WN (tungsten nitride), WSi (tungsten silicide), etc.

Also, as shown in FIG. 9, gate insulating films 305a are formed between gate electrode 305 and semiconductor substrate 301. Sidewall spacers 305b are formed with insulating films such as silicon nitride (Si₃N₄) and the like on sidewalls of gate electrodes 305. Insulating films 305c such as silicon nitride and the like are formed even on gate electrodes 305 thereby protecting an upper face of gate electrode 305.

Impurity diffusion layers 308 are formed by implanting N type impurities, for example, phosphorous into semiconductor substrate 301. Substrate contact plug 309 is formed to be in contact with impurity diffusion layer 308. The substrate contact plugs 309 are arranged at positions of substrate contact portions 405a, 405b, and 405c shown in FIG. 8, respectively, and are formed of polycrystalline silicon containing, for example, phosphorous. The width of horizontal direction (X direction) in substrate contact plug 309 is defined by sidewall spacers 305b formed on adjacent word lines W, and which is a self-aligned structure.

As shown in FIG. 9, first interlayer insulating film 304 is formed to cover substrate contact plug 309 and insulating film 305c on gate electrode, and bit line contact plug 304A is formed passing through first interlayer insulating film 304. Bit line contact plug 304A is arranged at a position of substrate contact portion 405a and communicated with substrate contact plug 309. Bit line contact plug 304A is formed by depositing metal film such as W and the like on a barrier film (TiN/Ti) formed of a stack film of Ti and TiN. Bit line 306 is formed to be connected to bit line contact plug 304A. Bit line 306 is formed of a stack film formed of WN and W.

Second interlayer insulating film 307 is formed to cover bit line 306. Storage-node contact plug 307A is formed to pass through first interlayer insulating film 304 and second interlayer insulating film 307 thereby being connected to substrate contact plug 309. Storage-node contact plug 307A is arranged at positions of substrate contact portions 405b, 405c. Second interlayer insulating film 307 is formed thereon with third interlayer insulating film 311 employing silicon nitride and fourth interlayer insulating film 312 employing silicon oxide.

Capacitors (Cap) are formed to pass through third interlayer insulating film 311 and fourth interlayer insulating film 312 thereby being connected to storage-node contact plug 307A.

Capacitors (Cap) are configured to sandwich capacitor dielectric film 314 formed using the present invention between lower electrode 313 and upper electrode 315. Lower electrode 313 is communicated with storage-node contact plug 307A. Lower electrode 313 and storage-node contact plug 307A can be connected to each other by introducing therebetween a pad that is formed of a conductive film.

Fourth interlayer insulating film 312 is formed thereon with fifth interlayer insulating film 320 formed of silicon oxide and the like, metal wiring layer 321 formed of Al, Cu, etc. and surface protecting film 322.

Upper electrode 315 of capacitor is applied with a predetermined potential, and functions as a DRAM device performing a memory operation on information by determining whether the capacitor maintains charges.

Next, method of forming capacitor (Cap) will be described in detail.

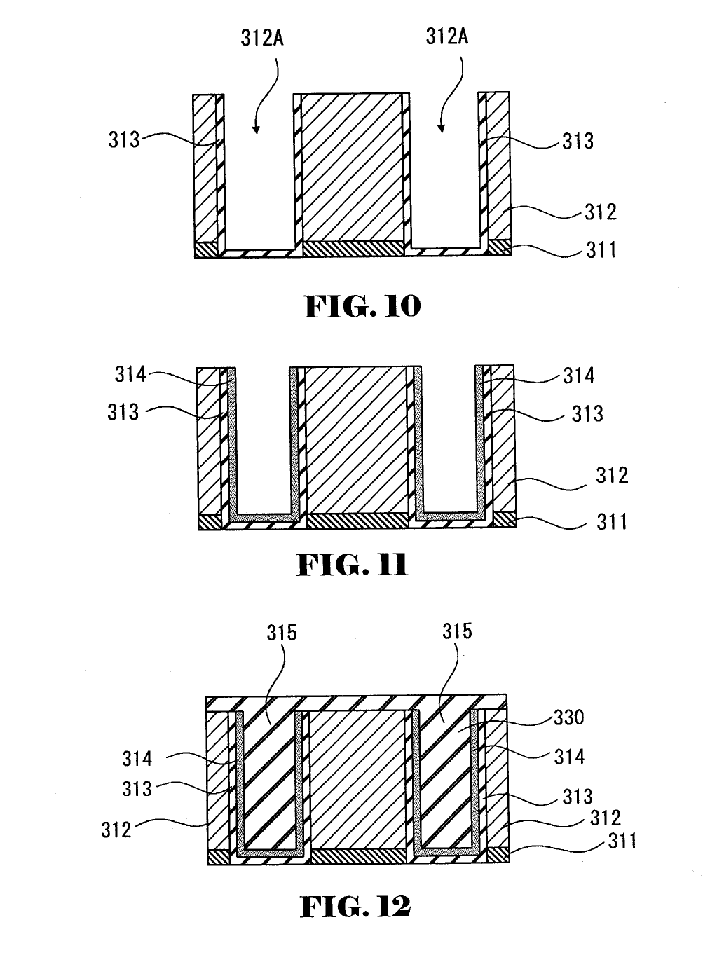

FIG. 10 to FIG. 12 are sectional views showing only upper portions above third interlayer insulating film 311.

First, as shown in FIG. 10, third interlayer insulating file 311 and fourth interlayer insulating film 312 are deposited to a predetermined film thickness, and then holes 312A, which become cylinder holes for forming a capacitor, are formed using a photolithography technique.

A Ru film as a lower electrode 313 is deposited and lower electrode 313 is formed using dry etching or CMP (chemical mechanical polishing) techniques so that the lower electrode can remain only at an inner wall part of hole 312A.

Other materials for forming lower electrode 313 include metal films such as Pt, Ti, Ir, W, Ta, etc. or nitride of these. The lower electrode can be formed of a metal film containing a plurality of elements or a stack film of a plurality of materials.

Next, as shown in FIG. 11, as a capacitor dielectric film 114, TiO₂ film containing Zr in a concentration of less than 40% is deposited to a thickness of 6 to 10 nm using the ALD method described in Exemplary Embodiment 3 (capacitor dielectric film above fourth interlayer insulating film 312 was omitted in the drawings). Thereafter, the resultant film is annealed at an oxygen atmosphere that is set at 500° C.

To prevent the lower electrode from being damaged at the time of annealing, it is preferable that the lower electrode is formed of oxidation-resistant materials (Pt, Ru, etc.). Also, a barrier film having a high oxidation-resistance may be arranged between a lower electrode and a capacitor dielectric film.

Next, as shown in FIG. 12, a Ru film is deposited to fill hole 312A, and then patterned to form upper electrode 315.

Other materials for forming upper electrode 315 include metal film such as Pt, Ti, Ir, W, Ta, etc. or nitride of these. Also, upper electrode can be formed with a stack film of a plurality of materials. The lower electrode and upper electrode can be formed of materials different from each other.

In this manner, capacitor (Cap) is completed.

In this exemplary embodiment, although the capacitor (Cap) is formed in a cylinder shape in which only an inner wall of lower electrode is used as electrode, it is possible to form a capacitor in a crown shape employing as an electrode both of an outer wall and an inner wall of lower electrode, or, in a pedestal shape employing as an electrode only an outer wall of lower electrode.

A capacitor dielectric film can be formed using a TiO₂ film containing Al in a concentration of less than 40%.

In the above exemplary embodiments, although the dielectric film is used as a capacitor dielectric film, the dielectric film can be used as various dielectric films for semiconductor device such as a gate dielectric film, which is required a high dielectric constant.

Further, the present invention includes the following aspects:

I. A method of fabricating a dielectric film comprising:
forming a dielectric film on a base by a film formation technique using a Ti source and a Zr or Al source simultaneously to produce a TiO₂ film containing Zr or Al in a concentration of less than 40% by a ratio of the number of atoms represented by (Zr or Al)/((Zr or Al)+Ti) with an approximately constant concentration profile in the direction of the film thickness.

II. The method of fabricating a dielectric film according to aspect I, wherein the film formation technique is a sputtering technique using a first target containing Ti and oxygen and a second target containing Zr or Al and oxygen, and by controlling RF power supplied to each of the targets.

III. The method of fabricating a dielectric film according to aspect I, wherein the film formation technique is an atomic layer deposition method which comprises:
(1) introducing a first raw material containing Ti and a second raw material containing Zr or Al with controlling the amounts thereof into a film formation space and depositing a material containing Zr or Al, and Ti on the base;
(2) purging the film formation space;
(3) introducing an oxidizing gas into the film formation space to oxidize the deposited material;
(4) purging the film formation space; and
(5) repeating the above steps (1)-(4) until the film thickness reaches to a predetermined value.

IV. The method of fabricating a dielectric film according to aspect III, wherein the first raw material and the second raw material all are prepared in a liquid state, sprayed and vaporized by a spray nozzle, and at the same time, mixed in a predetermined ratio, thereafter, passed through a vaporization chamber thereby generated as a source gas containing Zr or Al, and Ti, and supplied to the film formation space.

V. The method of fabricating a dielectric film according to aspect III, wherein a first source gas containing Ti is created from the first raw material, a second source gas containing Zr or Al is created from the second raw material, the first source gas and the second source gas are mixed in a predetermined ratio, thereafter supplied to the film formation space.

VI. The method of fabricating a dielectric film according to any of aspects I-V, wherein the dielectric film is deposited on the base, thereafter a process of annealing is performed at a temperature of 400 to 700° C. in an oxidizing atmosphere.

VII. The method of fabricating a dielectric film according to any of aspects I-VI, wherein the dielectric film comprises a TiO₂ film containing Zr of 10 to 40% by a ratio of the number of atoms represented by Zr/(Zr+Ti).

VIII. The method of fabricating a dielectric film according to any of aspects I-VI, wherein the dielectric film comprises a TiO₂ film containing Zr of 20 to 30% by a ratio of the number of atoms represented by Zr/(Zr+Ti).

IX. The method of fabricating a dielectric film according to any of aspects I-VI, wherein the dielectric film comprises a TiO₂ film containing Al of 10 to 40% by a ratio of the number of atoms represented by Al/(Al+Ti).

X. The method of fabricating a dielectric film according to any of aspects I-VI, wherein the dielectric film comprises a TiO₂ film containing Al of 20 to 30% by a ratio of the number of atoms represented by Al/(Al+Ti).

XI. The method of fabricating a dielectric film according to any of aspects I-X, wherein the base is a lower electrode of a capacitor.

XII. A method of fabricating a capacitor comprising:

forming a capacitor dielectric film on a lower electrode and

forming an upper electrode on the capacitor dielectric film,

wherein the capacitor dielectric film is formed by the method of fabricating a dielectric film according any of aspects I-XI.

XIII. The method of fabricating a capacitor according to aspect XII, wherein the lower electrode and the upper electrode are selected from metal films containing at least one of Ru, Pt, Ir, Ti, W and Ta.

IXX. A method of fabricating a semiconductor device comprising at least one dielectric film, wherein the method includes forming the dielectric film by the method of fabricating a dielectric film according any of aspects I-XI.

XX. The method of fabricating a semiconductor device,

wherein the method includes:
forming a switching device on a semiconductor substrate, and
forming a capacitor electrically connected to the switching device;

wherein the capacitor is formed by the method according to any of aspects XII-XIII.

What is claimed is:

1. A dielectric film comprising a TiO₂ film containing Zr or Al in a concentration of less than 40% by a ratio of the number of atoms represented by (Zr or Al)/((Zr or Al)+Ti) with an approximately constant concentration profile in the direction of the film thickness.

2. The dielectric film according to claim 1, wherein the dielectric film comprises a TiO₂ film containing Zr of 10 to 40% by a ratio of the number of atoms represented by Zr/(Zr+Ti).

3. The dielectric film according to claim 1, wherein the dielectric film comprises a TiO₂ film containing Zr of 20 to 30% by a ratio of the number of atoms represented by Zr/(Zr+Ti).

4. The dielectric film according to claim 1, wherein the dielectric film comprises a TiO₂ film containing Al of 10 to 40% by a ratio of the number of atoms represented by Al/(Al+Ti).

5. The dielectric film according to claim 1, wherein the dielectric film comprises a TiO₂ film containing Al of 20 to 30% by a ratio of the number of atoms represented by Al/(Al+Ti).

6. The dielectric film according to claim 1, wherein the dielectric film has a dielectric constant of more than 30.

7. A semiconductor device comprising a capacitor, the capacitor comprises;
a lower electrode;
a capacitor dielectric film on the lower electrode; and
an upper electrode on the capacitor dielectric film,
wherein the capacitor dielectric film comprises a TiO₂ film containing Zr or Al in a concentration of less than 40% by a ratio of the number of atoms represented by (Zr or Al)/((Zr or Al)+Ti) with an approximately constant concentration profile in the direction of the film thickness.

8. The semiconductor device according to claim 7, wherein the capacitor dielectric film comprises a TiO₂ film containing Zr of 10 to 40% by a ratio of the number of atoms represented by Zr/(Zr+Ti).

9. The semiconductor device according to claim 7, wherein the capacitor dielectric film comprises a TiO₂ film containing Zr of 20 to 30% by a ratio of the number of atoms represented by Zr/(Zr+Ti).

10. The semiconductor device according to claim 7, wherein the capacitor dielectric film comprises a TiO₂ film containing Al of 10 to 40% by a ratio of the number of atoms represented by Al/(Al+Ti).

11. The semiconductor device according to claim 7, wherein the capacitor dielectric film comprises a TiO₂ film containing Al of 20 to 30% by a ratio of the number of atoms represented by Al/(Al+Ti).

12. The semiconductor device according to claim 7, wherein the capacitor dielectric film has a dielectric constant of more than 30.

13. The semiconductor device according to claim 7, wherein the lower electrode and the upper electrode are selected from metal films containing at least one of Ru, Pt, Ir, Ti, W and Ta.

14. A semiconductor device comprising at least one dielectric film, wherein the dielectric film comprises a TiO₂ film containing Zr or Al in a concentration of less than 40% by a ratio of the number of atoms represented by (Zr or Al)/((Zr or Al)+Ti) with an approximately constant concentration profile in the direction of the film thickness.

15. The semiconductor device according to claim 14,
wherein the semiconductor device comprises a switching device and a capacitor electrically connected to the switching device provided on a semiconductor substrate,
wherein the capacitor comprises a lower electrode, a capacitor dielectric film on the lower electrode and an upper electrode on the capacitor dielectric film, and
wherein the capacitor dielectric film comprises said dielectric film.

16. The semiconductor device according to claim 14, wherein the dielectric film comprises a TiO₂ film containing Zr of 10 to 40% by a ratio of the number of atoms represented by Zr/(Zr+Ti).

17. The semiconductor device according to claim 14, wherein the dielectric film comprises a TiO₂ film containing Zr of 20 to 30% by a ratio of the number of atoms represented by Zr/(Zr+Ti).

18. The semiconductor device according to claim 14, wherein the dielectric film comprises a TiO₂ film containing Al of 10 to 40% by a ratio of the number of atoms represented by Al/(Al+Ti).

19. The semiconductor device according to claim 14, wherein the capacitor dielectric film comprises a TiO₂ film containing Al of 20 to 30% by a ratio of the number of atoms represented by Al/(Al+Ti).

20. The semiconductor device according to claim 14, wherein the dielectric film has a dielectric constant of more than 30.
